(19) United States
(12) Patent Application Publication
(10) Pub. No.: US 2007/0176225 A1
(43) Pub. Date: Aug. 2, 2007

(54) Semiconductor device and method of manufacturing the same

(76) Inventors: Sang-Hoon Lee, Seoul (KR); Ki-Su Na, Yongin-si (KR); Man-Sug Kang, Suwon-si (KR); Yong-Sun Lee, Suwon-si (KR); Yong-Seok Kim, Seoul (KR); Tae-Jong Lee, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/700,083

(22) Filed: Jan. 31, 2007

(30) Foreign Application Priority Data
Feb. 1, 2006 (KR) 2006-9635

(51) Int. Cl. H01L 29/788; H01L 21/8238

(52) U.S. Cl. 257/315; 438/211; 257/E29.129

(57) ABSTRACT

A semiconductor device having reduced pitting may be formed from isolation layer patterns on a semiconductor substrate defining an active region, a tunnel oxide layer on the active region, the tunnel oxide layer having a nitrified surface, a floating gate on the tunnel oxide layer, a dielectric layer on the floating gate, and a control gate on the dielectric layer.

### BACKGROUND OF THE INVENTION

1. Field of the Invention

The present invention relates to a semiconductor device and a method of manufacturing the semiconductor device, more particularly, to a non-volatile semiconductor device including a floating gate and a method of manufacturing the non-volatile semiconductor device having the floating gate.

2. Description of the Related Art

Non-volatile semiconductor devices generally maintain stored data even when the power is turned off. As a result, non-volatile semiconductor memory devices, e.g., flash memory devices, have been widely applied in various electronic apparatuses because data may be easily programmed or erased in these memory devices.

A non-volatile semiconductor device may usually include a floating gate capable of storing charges. The floating gate may have a structure substantially similar to that of a metal oxide semiconductor (MOS) transistor. A tunnel oxide layer may be formed between a semiconductor substrate and the floating gate. A dielectric layer and a control gate may be sequentially formed on the floating gate. Accumulation of charges in the floating gate may vary in accordance with various parameters, e.g., electrical characteristics of the tunnel oxide layer, surface roughness of the semiconductor substrate, surface roughness of the floating gate, etc.

In a non-volatile semiconductor device, data may be stored by a Fowler-Nordheim (F-N) tunneling method or by a hot electron injection method. The F-N tunneling method may apply a high electric field the tunnel oxide layer while a high voltage may be applied to the control gate. Charges such as electrons may accumulate in the floating gate via the high electric field from the semiconductor substrate through the tunnel oxide layer. Thus, the surface roughness of the floating gate may have a large effect on a programming operation of the non-volatile semiconductor device while storing the data in the floating gate. In the hot electron method, hot electrons generated from a drain region may be injected into the floating gate through the tunnel oxide layer after applying high voltages to the control gate and the drain region.

According to the F-N tunneling and the hot electron injection methods, the high electric field may be applied to the tunnel oxide layer so as to store charges in the floating gate. The non-volatile semiconductor device may have a high coupling ratio in order to adequately apply the high electric field to the tunnel oxide layer. The coupling ratio (C_{R}) of the non-volatile semiconductor device may be generally represented by the following Equation 1:

C_{R}=C_{ONO}/(C_{TUN}+C_{ONO}) (Equation 1)

In the above Equation 1, C_{ONO} is a storage capacity between a control gate and a floating gate, and C_{TUN} is a storage capacity of a tunnel oxide layer between a semiconductor substrate and the floating gate. To increase the coupling ratio of the non-volatile semiconductor device, a portion of the floating gate superimposed with the control gate may have an increased surface area.

On the other hand, the thickness of the floating gate may be reduced as the degree of integration of the non-volatile semiconductor device is greatly increased. When the floating gate has a thin thickness, pitting of an active region of the semiconductor device may frequently occur during an etching process for forming the floating gate. As a result, new technologies are desired that may reduce pitting to produce improved flash memory devices.

### SUMMARY OF THE INVENTION

The present invention is therefore directed to a semiconductor device including a floating gate, which substantially overcomes one or more of the problems due to the limitations and disadvantages of the related art.

Therefore, example embodiments of the present invention provide a semiconductor device and a method of manufacturing a semiconductor device including a floating gate having improved surface roughness.

At least one of the above and other features of the present invention may be realized by providing a semiconductor device including isolation layer patterns that may be on a semiconductor substrate to define an active region, and a tunnel oxide layer may be on the active region, where the tunnel oxide layer may have a nitrified surface. A floating gate may be formed on the tunnel oxide layer. A dielectric layer may be formed on the floating gate. A control gate may be formed on the dielectric layer. The floating gate may have a first floating gate pattern and a second floating gate pattern.

The first floating gate pattern may have a thickness of about 50 Å to about 100 Å, and the second floating gate pattern may have a thickness of about 100 Å to about 200 Å. The first floating gate pattern may include amorphous silicon having a first impurity concentration, and the second floating gate pattern may include amorphous silicon having a second impurity concentration substantially different from the first impurity concentration. The first floating gate pattern may include amorphous silicon without impurities, and the second floating gate pattern may include amorphous silicon doped with impurities.

The first and the second floating gate patterns together may have a U shape. A thickness ratio between the first floating gate pattern and the second floating gate pattern may be in a range of about 1.0:1.0 to about 1.0:4.0. The dielectric layer may include oxide, nitride or metal oxide, or the dielectric layer may have an oxide/nitride/oxide (ONO) structure. The control gate may include polysilicon doped with impurities or metal silicide.

At least one of the above and other features and advantages of the present invention may be realized by providing a method of manufacturing a semiconductor device that may include forming isolation layer patterns on a semiconductor substrate to define an active region. A tunnel oxide layer may be formed on the active region, and then a surface of the tunnel oxide layer may be nitrified. A floating gate may be formed on the tunnel oxide layer. A dielectric layer may be formed on the floating gate. A control gate may be formed on the dielectric layer.

The tunnel oxide layer may be formed by a thermal oxidation process. The nitrified surface of the tunnel oxide layer may be formed by a plasma nitration process using nitrogen-containing plasma. In the formation of the floating gate, a first floating gate pattern may be formed on the tunnel oxide layer using polysilicon substantially without impurities. Then, a second floating gate pattern may be formed on the first floating gate pattern using polysilicon doped with impurities. The first floating gate pattern may be formed at a first temperature under a first pressure, and the second floating gate pattern may formed at a second temperature under a second pressure. The first temperature and the first pressure may be substantially the same as the second temperature and the second pressure, respectively. The first and the second temperatures may be in a range of about 450° C. to about 550° C., and the first and the second pressures may be in a range above about 130 Pa. The first floating gate pattern and the second floating gate pattern may be formed in-situ. A filling layer may be formed on the second floating gate. The filling layer may be formed using oxide or organic polymer.

### BRIEF DESCRIPTION OF THE DRAWINGS

The above and other features and advantages of the present invention will become more apparent to those of ordinary skill in the art by describing in detail example embodiments thereof with reference to the attached drawings, in which:

FIGS. 1 to 7 illustrate cross-sectional views of stages in a method of manufacturing a semiconductor device in accordance with example embodiments of the present invention;

FIG. 8A is an electron photomicrograph of a surface of a floating gate in a related art semiconductor device obtained using a scanning electron microscope (SEM);

FIG. 8B is an electron photomicrograph of the surface of the floating gate in the related art semiconductor device obtained using an atomic force microscope (AFM);

FIG. 9A is an electron photomicrograph of a surface of a floating gate in a semiconductor device obtained using an SEM according to an example embodiment of the present invention;

FIG. 9B is an electron photomicrograph of the surface of the floating gate in the semiconductor device obtained using an AFM according to an example embodiment of the present invention;

FIGS. 10A to 10E are electron photomicrographs of cross-sections of floating gates in a related art semiconductor device; and

FIGS. 11A to 11E are electron photomicrographs of cross-sections of floating gates in a semiconductor device according to example embodiments of the present invention.

### DETAILED DESCRIPTION OF THE INVENTION

Korean Patent Application No. 2006-9635 filed on Feb. 1, 2006, in the Korean Intellectual Property Office, and entitled: “Semiconductor Device and Method of Manufacturing the Same,” is incorporated by reference herein in its entirety.

The present invention will now be described more fully hereinafter with reference to the accompanying drawings, in which example embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the drawing figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

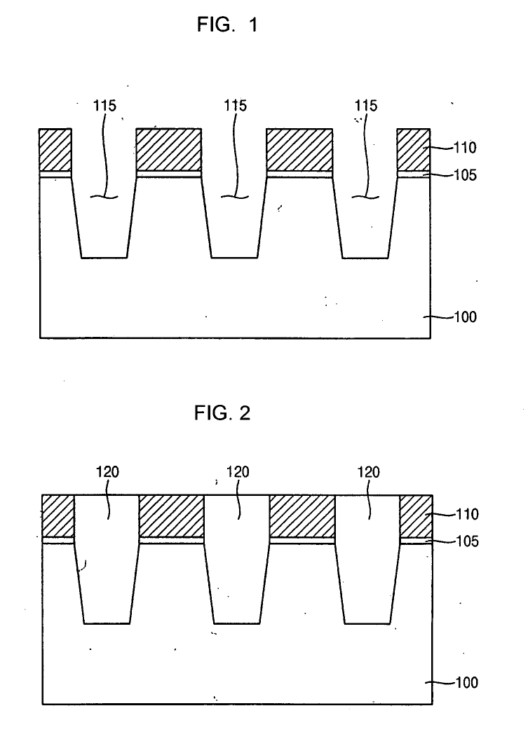

FIGS. 1 to 7 illustrate cross-sectional views of steps of a method of manufacturing a semiconductor device in accordance with example embodiments of the present invention. Although a method of manufacturing a non-volatile semiconductor device, e.g., a flash memory device may be illustrated in FIGS. 1 to 7, the features and advantages of the present invention may be employed in manufacturing other volatile semiconductor devices, e.g., dynamic random access memory (DRAM) devices or static random access memory (SRAM) devices.

FIG. 1 illustrates a cross-sectional view trenches 115 formed at upper portions of a semiconductor substrate 100.

FIG. 1 depicts a pad oxide layer pattern 105 and a mask pattern 110 that may be sequentially formed on the semiconductor substrate 100. The semiconductor substrate 100 may include silicon. For example, the semiconductor substrate 100 may include a silicon wafer, a silicon germanium substrate, a silicon-on-insulator substrate, etc. Alternately, the semiconductor substrate 100 may be formed from gallium arsenide.

The pad oxide layer pattern 105 and the mask pattern 110 may be formed by forming a pad oxide layer and a mask layer on the semiconductor substrate 100, followed by patterning the pad oxide layer and the mask layer. The pad oxide layer and the mask layer may be patterned by, e.g., a photolithographic process.

In one example embodiment of the present invention, the pad oxide layer may be formed by, e.g., a thermal oxidation process. That is, the pad oxide layer may be formed by partially oxidizing the semiconductor substrate 100. In another example embodiment of the present invention, the pad oxide layer may be formed by depositing an oxide on the semiconductor substrate 100. For example, the pad oxide layer may be formed by, e.g., a chemical vapor deposition (CVD) process. The pad oxide layer pattern 105 may reduce stress generated between the semiconductor substrate 100 and the mask pattern 110.

In some example embodiments of the present invention, the mask layer may be formed by, e.g., a low pressure chemical vapor deposition (LPCVD) process, a plasma-enhanced chemical vapor deposition process (PECVD), an atomic layer deposition (ALD) process, etc. The mask pattern 110 may include a material that has etching selectivity relative to the pad oxide layer pattern 105 and the semiconductor substrate 100. For example, the mask pattern 110 may be formed using a nitride, e.g., silicon nitride.

Using the mask pattern 110 as an etching mask, the upper portions of the semiconductor substrate 100 may be etched to form trenches 115. When the trenches 115 may be formed at the upper portions of the semiconductor substrate 100, then active regions and field regions may be defined. Each of the trenches 115 may have a predetermined depth in accordance with required electrical characteristics of the semiconductor device. In some example embodiments of the invention, the trenches 115 may have sidewalls inclined with respect to the semiconductor substrate 100. Further, inner oxide layers may be formed on the sidewalls and bottoms of the trenches 115 to cure damage to the semiconductor substrate 100 generated during the etching process that may be used for forming the trenches 115. The inner oxide layers may be formed by oxidizing the sidewalls and the bottoms of the trenches 115.

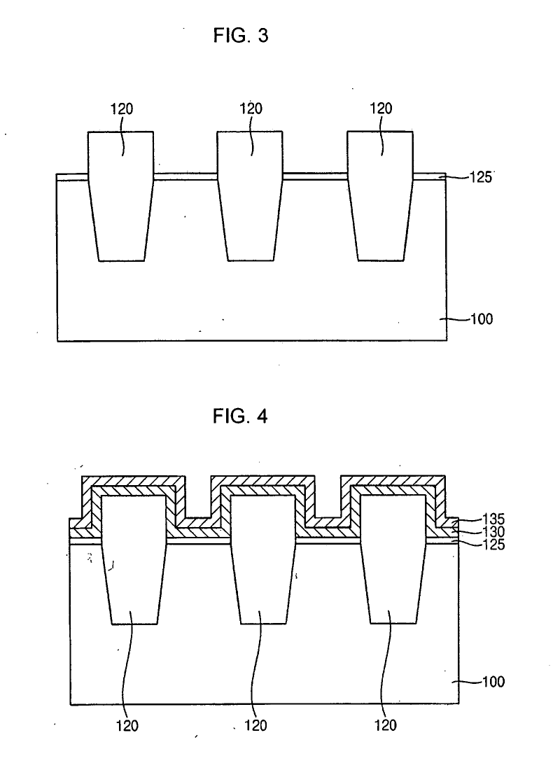

FIG. 2 illustrates a cross-sectional view of preliminary isolation layer patterns 120 filling the trenches 115.

In FIG. 2, an oxide layer may be formed on the mask pattern 110 to fill the trenches 115. The oxide layer may be removed until the mask pattern 110 is exposed, thereby forming the preliminary isolation layer patterns 120 in the trenches 115. The oxide layer may be formed by, e.g., a CVD process, a PECVD process, a high density plasma-chemical vapor deposition (HDP-CVD) process, an ALD process, etc. Further, the oxide layer may be formed using a silicon oxide-containing material such as boron-phosphorous-silicate glass (BPSG), phosphorous-silicate glass (PSG), undoped silicate glass (USG), spin-on-glass (SOG), flowable oxide (FOX), tetraethylorthosilicate (TEOS), plasma-enhanced tetraethylorthosilicate (PE-TEOS), HDP-CVD oxide, quartz, etc. These materials may be used alone or in a mixture thereof. The preliminary isolation layer patterns 120 may be formed by, e.g., a chemical mechanical polishing (CMP) process, an etch-back process or a combination process of CMP and etch back. When the preliminary isolation layer patterns 120 may be formed in the trenches 115, then the active regions and the field regions may be defined on the semiconductor substrate 100. That is, the preliminary isolation layer patterns 120 may correspond to the field region, and portions of the semiconductor substrate 100 between the preliminary isolation layer patterns 120 may correspond to the active regions.

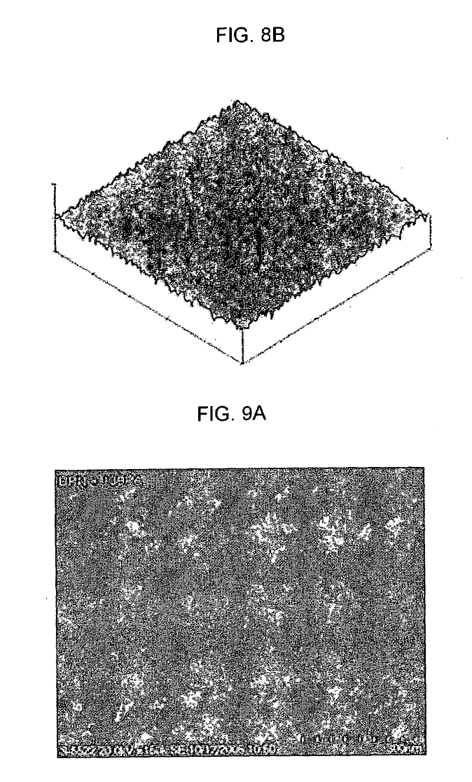

Each of the preliminary isolation layer patterns 120 may have a height substantially the same as that of the mask pattern 110. The preliminary isolation layer patterns 120 may serve as molds for forming floating gates 155 (see FIG. 5) by, e.g., a self-aligned poly selected area polishing (SAP) process. However, the heights of the preliminary isolation layer patterns 120 may vary in accordance with the particular design rule and coupling ratio of the semiconductor device.

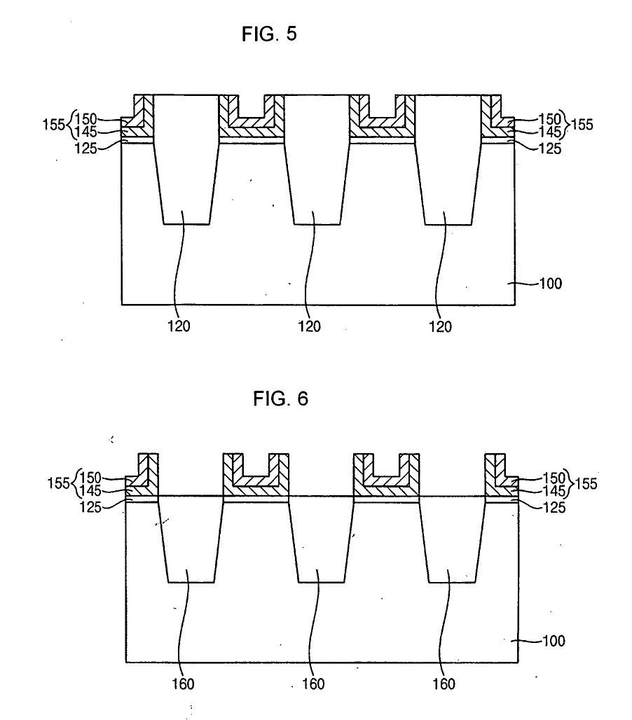

FIG. 3 illustrates a cross-sectional view of tunnel oxide layers 125 formed on the semiconductor substrate 100.

FIG. 3 shows that the active regions between the preliminary isolation layer patterns 120 may be exposed by removing the pad oxide layer pattern 105 and the mask layer 110 from the semiconductor substrate 100. The tunnel oxide layers 125 may be formed on the exposed active regions. When the mask pattern 110 and the pad oxide layer pattern 105 are removed, the preliminary isolation layer patterns 120 may protrude from an upper face of the semiconductor substrate 100. Since a number of charges, such as electrons or holes, may pass through the tunnel oxide layers 125 during a programming operation and/or an erasing operation, the tunnel oxide layers 125 may include an oxide having good qualities. Each of the tunnel oxide layers 125 may have a thickness of about 40 Å to about 100 Å, preferably from about 60 Å to about 80 Å, measured from the upper face of the semiconductor substrate 100. In one example embodiment of the invention, the tunnel oxide layers 125 may be formed by a thermal oxidation process. Namely, each of the tunnel oxide layers 125 may be formed by partially oxidizing the active region. The tunnel oxide layers 125 may thus include silicon oxide. In other example embodiments of the invention, the tunnel oxide layers 125 may be formed on the active region by, e.g., a CVD process, an LPCVD process, an ALD process, a PECVD process, etc. Here, each of the tunnel oxide layers 125 may include an oxide, a nitride or a metal oxide. For example, each of the tunnel oxide layers 125 may include, e.g., silicon oxide, silicon nitride, hafnium oxide, zirconium oxide, tantalum oxide, titanium oxide, etc.

When the tunnel oxide layers 125 serve as nucleation layers for forming the floating gates 155, a nitration process may be performed on the tunnel oxide layers 125 to improve surface densities of the tunnel oxide layers 125. The nitration process may be carried out using a nitrogen-containing plasma. For example, the nitrogen-containing plasma may be generated from, e.g., nitrogen (N₂) gas, ammonia (NH₃) gas, nitrogen monoxide (NO) gas, nitrous oxide (N₂O) gas, etc. These gases can be used alone or in a mixture thereof. Also, other inert gases may be in the plasma.

In some example embodiments of the present invention, the semiconductor substrate 100 may be loaded into a chamber, and then the plasma may be generated over the semiconductor substrate 100 in the chamber. The plasma may be generated by, e.g., a direct plasma process. Alternatively, the plasma may be formed by, e.g., a remote plasma process. Surfaces of the tunnel oxide layers 125 may be nitrified by the plasma in the chamber.

When the surfaces of the tunnel oxide layers 125 have been nitrified using the plasma, then amorphous silicon layers of the floating gates 155 may be formed on the tunnel oxide layers 125 to improve the surface roughness. In a non-volatile semiconductor device such as a flash memory device, threshold voltages (Vth) of memory cells in the non-volatile semiconductor device may mainly depend on the thickness of the tunnel oxide layers 125. That is, a thickness variation of the tunnel oxide layers 125 may have a large effect on the electrical characteristics of the non-volatile semiconductor device. Therefore, each of the tunnel oxide layers 125 may have a uniform thickness from an upper face of the active region. Further, the surface characteristics of the tunnel oxide layers 125 may be enhanced by the floating gates 155 because the surface characteristics of the tunnel oxide layers 125 may affect the growth of the amorphous silicon layers for the floating gates 155. As a result, the plasma nitration process may be performed on the tunnel oxide layers 125, thereby ensuring a uniform thickness of the tunnel oxide layers 125 and thus improving the surface characteristics of the tunnel oxide layers 125.

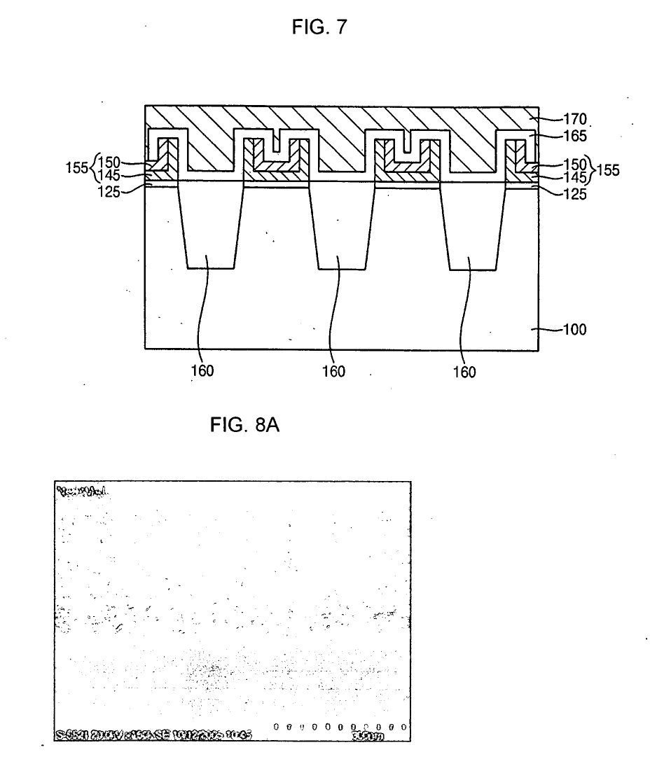

FIG. 4 illustrates a cross-sectional view of a first floating gate layer 130 and a second floating gate layer 135 formed on the tunnel oxide layers 125 and the preliminary isolation layers 120.

Referring to FIG. 4, the first floating gate layer 130 may be conformably formed on the preliminary isolation layer patterns 120 and the tunnel oxide layers 125 nitrified by the plasma nitration process. The first floating gate layer 130 may be formed by, e.g., a CVD process or an ALD process. The first floating gate layer 130 may be formed using amorphous silicon having a first impurity concentration. The first floating gate layer 130 may be formed using, e.g., undoped amorphous silicon. The first floating gate layer 130 may be formed at a relatively low first temperature and a relatively high first pressure. For example, the first floating gate layer 130 may be formed at a first temperature of about 450° C. to about 550° C., e.g., about 475° C. to about 525° C., at a first pressure that may be above about 130 Pa. The first floating gate layer 130 may have a first thickness based on an upper faces of the tunnel oxide layers 125. For example, the first floating gate layer 130 may have the first thickness of about 50 Å to about 100 Å, e.g., about 60 Å to about 90 Å.

The second floating gate layer 135 may be formed on the first floating gate layer 130 by, e.g., a CVD process or an ALD process. The second floating gate layer 135 may be formed using amorphous silicon having a second impurity concentration that may be substantially different from the first impurity concentration. For example, the second floating gate layer 135 may be formed using amorphous silicon doped with impurities. The second floating gate layer 135 may be formed at a relatively low second temperature under a relatively high second pressure. For example, the second floating gate layer 135 may be formed at a second temperature of about 450° C., to about 550° C., e.g., about 475° to about 525°, at a second pressure that may be above about 130 Pa. In one example embodiment of the present invention, the first and the second floating gate layers 130 and 135 may be formed at substantially the same temperature under the same pressure. In another example embodiment of the present invention, the first and the second floating gate layers 130 and 135 may be formed at substantially different temperatures and under different pressures.

The second floating gate layer 135 may have a second thickness based on an upper face of the first floating gate layer 130. For example, the second floating gate layer 135 may have the second thickness of about 100 Å to about 200 Å, e.g., about 125 Å to about 175 Å. Thus, a thickness ratio between the first floating gate layer 130 and the second floating gate layer 135 may be in a range of about 1.0:1.0 to about 1.0:4.0.

In an example embodiment of the present invention, the first and the second floating gate layers 130 and 135 may be formed in-situ using one chamber.

As described above, the first and the second floating gate layers 130 and 135 may have an improved surface roughness because the first and the second floating gate layers 130 and 135 are formed on the tunnel oxide layers 125 having nitrified surfaces. That is, the first and the second amorphous silicon floating gate layers having improved surface roughness may be formed on the tunnel oxide layers 125.

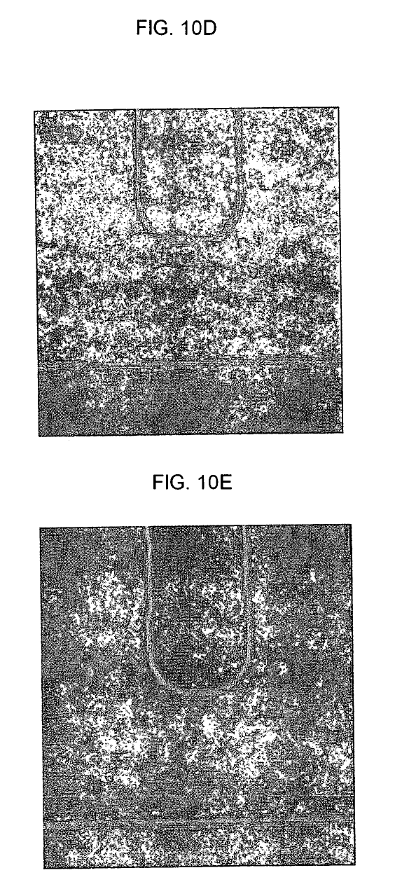

In order to better illustrate the advantages of the present invention over the related art, electron photomicroscopy was performed on examples of floating gate layers of the present invention and compared to the examples of the related art, as are shown in FIGS. 8A to 11E.

FIG. 8A is an electron photomicrograph of a surface of a floating gate in a related art semiconductor device obtained using a scanning electron microscope (SEM), and FIG. 8B is an electron photomicrograph of the surface of the floating gate in a related art semiconductor device obtained using an atomic force microscope (AFM). In FIGS. 8A and 8B, the floating gate including a single polysilicon film may be formed on a tunnel oxide layer without a plasma nitration process.

As shown in FIGS. 8A and 8B, the floating gate of the related art semiconductor device has poor surface roughness. That is, the surface of the floating gate of the related art semiconductor device exhibits considerable roughness. Particularly, the surface of the floating gate of the related art semiconductor device has a root mean square (RMS) value of about 1.364 nm, and a maximum roughness (RMAX) of the surface of the floating gate in the related art semiconductor device is about 13.55 nm, as shown in FIG. 8B.

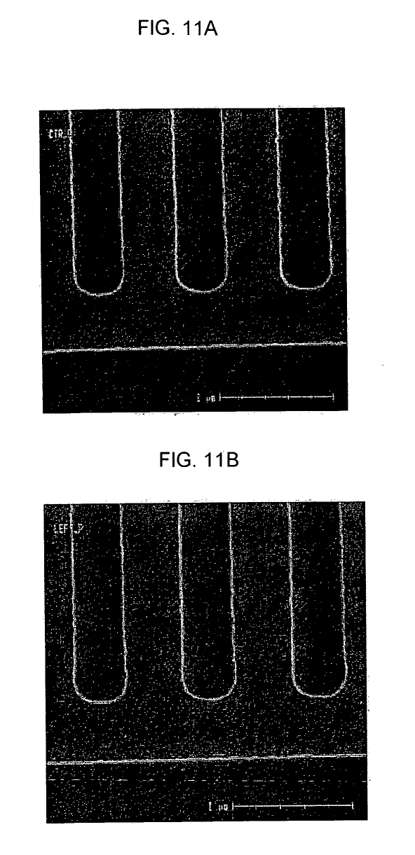

FIG. 9A is an SEM electron photomicrograph of a surface of a floating gate in a semiconductor device according to example embodiment of the present invention, and FIG. 9B is an AFM electron photomicrograph of the surface of the floating gate in the semiconductor device according to an example embodiment of the present invention. In FIGS. 9A and 9B, the floating gate including a first floating gate pattern and a second floating gate pattern is formed on a tunnel oxide layer having a nitrified surface in a plasma nitration process.

As shown in FIGS. 9A and 9B, the floating gate in the semiconductor device has a surface roughness greatly improved in comparison to the related art floating gate. Particularly, the surface of the floating gate in the semiconductor device has an RMS value of about 0.481 nm, and an RMAX value of the surface of the floating gate in the semiconductor device is about 4.483 nm, as shown in FIG. 9B. Thus, the RMS and the RMAX values of the surface of the floating gate according to the present invention are smaller than those of the surface of the related art floating gate by about 65% and about 67%, respectively.

When a floating gate has poor surface roughness, pitting of an active region and/or a semiconductor substrate may frequently occur during the successive etching processes for forming the floating gate. However, according to the present invention, the pitting of the active regions and/or other portions of the semiconductor substrate 100 may be effectively prevented because the first and the second floating gate layers 130 and 135 have improved surface roughness values.

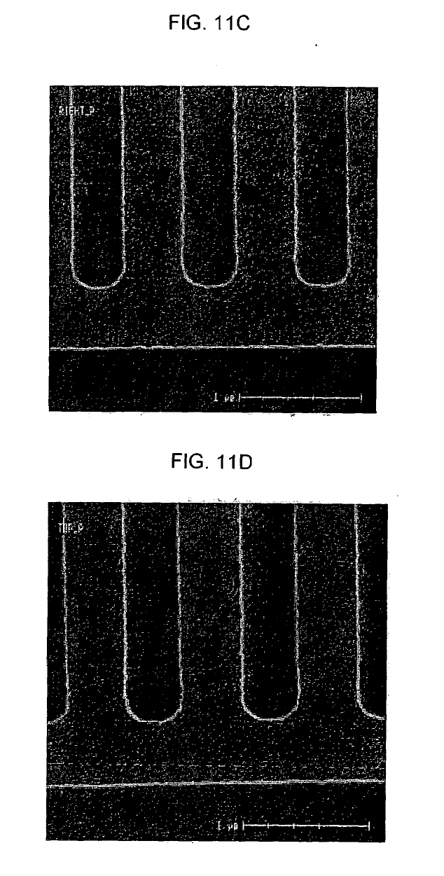

FIGS. 10A to 10E are electron photomicrographs of cross-sections of floating gates in a related art semiconductor device. FIG. 10A illustrates one floating gate formed on a central portion of a semiconductor substrate, and FIGS. 10B to 10E illustrate other floating gates formed on four peripheral portions of the semiconductor substrate.

As shown in FIGS. 10A to 10E, although hardly any pitting generates on the active region (see FIG. 10A) adjacent to the floating gate of the central portion in the semiconductor substrate, a significant number of pits are detected on other active regions (see FIGS. 10B to 10E) adjacent to other floating gates of the peripheral portions of the semiconductor substrates.

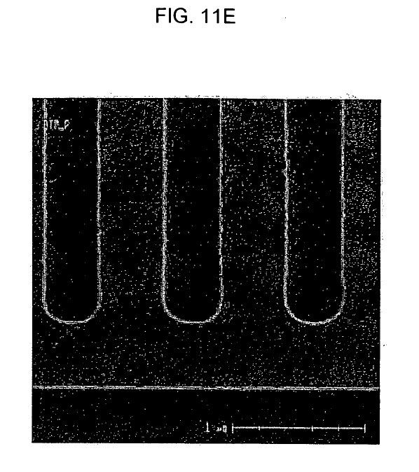

FIGS. 11A to 11E are electron photomicrographs of cross-sections of floating gates in a semiconductor device according to example embodiments of the present invention. FIG. 11A illustrates one floating gate formed on a central portion of a semiconductor substrate, and FIGS. 11B to 11E illustrate the floating gates formed on four peripheral portions of the semiconductor substrate.

As shown in FIGS. 11A to 11E, there is no pitting of the active region (see FIG. 11A) adjacent to the floating gate on the central portion of the semiconductor substrate as well as the active regions (see FIGS. 11B to 11E) adjacent to the floating gates on the peripheral portions of the semiconductor substrate.

According to some example embodiments of the present invention, the floating gates 155 may have a greatly improved surface roughness, and the pitting of the active regions adjacent to the floating gates 155 may be efficiently prevented when the first and the second floating gate layers 130 and 135 are formed on the tunnel oxide layers 125, which may be nitrified, i.e., by the plasma nitration process.

Remaining stages in a method of manufacturing the semiconductor of the present invention will now be described with reference to FIGS. 5 to 7.

FIG. 5 illustrates a cross-sectional view of floating gates 155 formed on the tunnel oxide layers 125, respectively.

In FIG. 5, the first and the second floating gate layers 130 and 135 may be partially removed until the preliminary isolation layer patterns 120 are exposed, so that the floating gates 155 may be formed on the tunnel oxide layer patterns 125. Each of the floating gates 155 may include a first floating gate pattern 145 and a second floating gate pattern 150. The first and the second floating gate patterns 145 and 150 may be formed by, e.g., a CMP process and/or an etch-back process.

In an example embodiment of the present invention, a filling layer may be formed on the second floating gate layer 135 before forming the first and the second floating gate patterns 145 and 150. The filling layer may be formed using an oxide, e.g., silicon oxide, or organic polymer. The filling layer may protect the floating gates 155 and/or the semiconductor substrate 100 in the process for partially removing the first and the second floating gate layers 130 and 135.

The first and the second floating gate patterns 145 and 150 may be formed on the tunnel oxide layer 125 between the preliminary isolation layer patterns 120. The first and the second floating gate patterns 145 and 150 may together have a U shape. That is, each of the floating gates 155 may have a U shape.

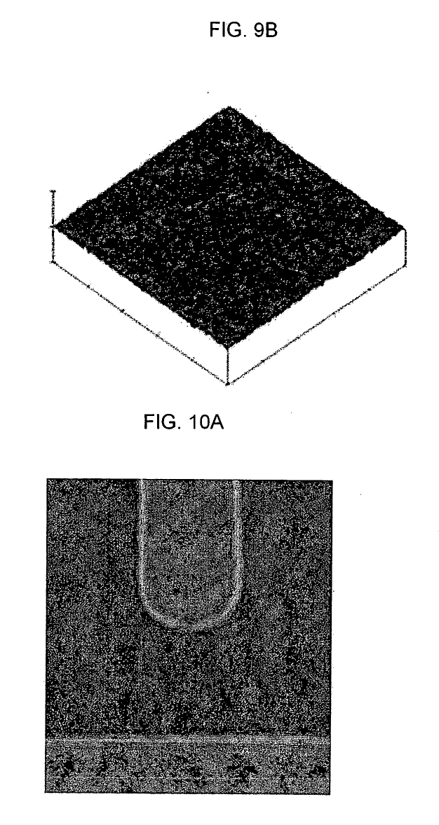

FIG. 6 illustrates a cross-sectional view of isolation layer patterns 160 formed on the active regions.

In FIG. 6, the preliminary isolation layer patterns 120 between the floating gates 155 may be partially removed to form the isolation layer patterns 160. When the isolation layer patterns 160 are formed on the semiconductor substrate 100, the field regions of the semiconductor substrate 100 may be completed so that the floating gates 155 may protrude from the semiconductor substrate 100.

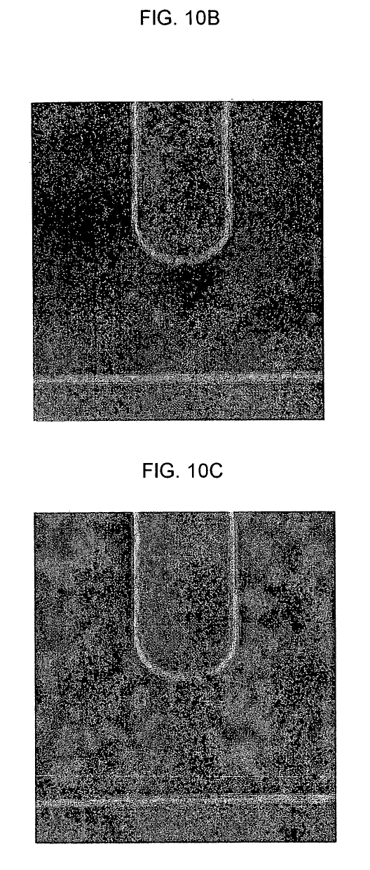

FIG. 7 illustrates a cross-sectional view of a dielectric layer 165 and a floating gate 170 formed on the isolation layer patterns 160 and the floating gates 155.

In FIG. 7, the dielectric layer 165 may be formed on the isolation layer patterns 160 and the floating gates 155. In one example embodiment of the present invention, the dielectric layer 165 may be formed using an oxide, e.g., silicon oxide. In another example embodiment of the present invention, the dielectric layer 165 may be formed using a nitride, e.g., silicon nitride. In still another example embodiment of the present invention, the dielectric layer 165 may be formed using a metal oxide having a high dielectric constant. For example, the dielectric layer 165 may be formed using, e.g., hafnium oxide, zirconium oxide, titanium oxide, tantalum oxide, etc. These can be used alone or as a mixture thereof. In still another example embodiment of the present invention, the dielectric layer 165 may have an oxide/nitride/oxide (ONO) structure that includes a lower oxide film, a nitride film and an upper oxide film. Further, the dielectric layer 165 may be formed by an LPCVD process. The dielectric layer 165 may have a thickness of about 100 Å to about 200A, preferably from about 125 Å to about 175 Å, measured from upper faces of the floating gates 155.

The control gate 170 may be formed on the dielectric layer 165. The control gate 170 may be formed using, e.g., polysilicon doped with impurities or a metal silicide. For example, the control gate 170 may be formed using, e.g., tungsten silicide, titanium silicide, cobalt silicide, etc. These may be used alone or as a mixture thereof.

In an example embodiment of the present invention, a capping layer (not shown) may be formed on the control gate 170 in order to protect the control gate 170 in successive processes. Additionally, the capping layer may electrically insulate the control gate 170 from a wiring (not shown) formed over the control gate 170. The capping layer may be formed using a nitride such as silicon nitride or an oxynitride, e.g., silicon oxynitride or titanium oxynitride.

Also, an insulating interlayer (not shown), a metal wiring (not shown) and/or a protection layer (not shown) may be formed on the control gate 170, such that the semiconductor device may be formed on the semiconductor substrate 100.

According to the present invention, a surface of a tunnel oxide layer may be nitrified by a plasma nitration process, and then a floating gate including a first floating gate pattern and a second floating gate pattern may be formed on the tunnel oxide layer. The first floating gate pattern may have a first impurity concentration, and the second floating gate pattern may have a second impurity concentration substantially different from the first impurity concentration. Since the floating gate may have an improved surface roughness, a pitting of an active region adjacent to the floating gate may be effectively prevented. As a result, a semiconductor device including the floating gate may have a uniform threshold voltage distribution and enhanced electrical characteristics.

Example embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
isolation layer patterns on a semiconductor substrate defining an active region;
a tunnel oxide layer on the active region, the tunnel oxide layer having a nitrified surface;
a floating gate on the tunnel oxide layer;
a dielectric layer on the floating gate; and
a control gate on the dielectric layer.

2. The semiconductor device as claimed in claim 1, wherein the floating gate comprises a first floating gate pattern and a second floating gate pattern.

3. The semiconductor device as claimed in claim 2, wherein the first floating gate pattern has a thickness of about 50 Å to about 100 Å, and the second floating gate pattern has a thickness of about 100 Å to about 200 Å.

4. The semiconductor device as claimed in claim 2, wherein the first floating gate pattern includes amorphous silicon having a first impurity concentration and the second floating gate pattern includes amorphous silicon having a second impurity concentration substantially different from the first impurity concentration.

5. The semiconductor device as claimed in claim 2, wherein the first floating gate pattern comprises amorphous silicon without impurities and the second floating gate pattern includes amorphous silicon doped with impurities.

6. The semiconductor device as claimed in claim 2, wherein the first and the second floating gate patterns together have a U shape.

7. The semiconductor device as claimed in claim 2, wherein a thickness ratio between the first floating gate pattern and the second floating gate pattern is in a range of about 1.0:1.0 to about 1.0:4.0.

8. The semiconductor device as claimed in claim 1, wherein the dielectric layer comprises oxide, nitride or metal oxide.

9. The semiconductor device as claimed in claim 1, wherein the dielectric layer comprises an oxide/nitride/oxide (ONO) structure.

10. The semiconductor device as claimed in claim 1, wherein the control gate comprises polysilicon doped with impurities, or metal silicide.

11. A method of manufacturing a semiconductor device, comprising:
forming isolation layer patterns on a semiconductor substrate to define an active region;
forming a tunnel oxide layer on the active region;
nitrifying a surface of the tunnel oxide layer;
forming a floating gate on the tunnel oxide layer;
forming a dielectric layer on the floating gate; and
forming a control gate on the dielectric layer.

12. The method as claimed in claim 11, wherein the tunnel oxide layer is formed by a thermal oxidation process.

13. The method as claimed in claim 11, wherein the nitrified surface of the tunnel oxide layer is formed by a plasma nitration process using a nitrogen-containing plasma.

14. The method as claimed in claim 11, wherein forming the floating gate comprises:
forming a first floating gate pattern on the tunnel oxide layer using polysilicon substantially without impurities; and
forming a second floating gate pattern on the first floating gate pattern using polysilicon doped with impurities.

15. The method as claimed in claim 14, wherein the first floating gate pattern is formed at a first temperature under a first pressure, and the second floating gate pattern is formed at a second temperature under a second pressure.

16. The method as claimed in claim 15, wherein the first temperature and the first pressure are substantially the same as the second temperature and the second pressure, respectively.

17. The method as claimed in claim 16, wherein the first and the second temperatures are in a range of about 450° C. to about 550° C., and the first and the second pressures are in a range above about 130 Pa.

18. The method as claimed in claim 14, wherein forming the first floating gate pattern and forming the second floating gate pattern are performed in-situ.

19. The method as claimed in claim 14, wherein forming the floating gate further comprises forming a filling layer on the second floating gate pattern.

20. The method as claimed in claim 14, wherein the filling layer is formed using oxide or organic polymer.
